(19) United States
(12) Patent Application Publication
(10) Pub. No.: US 2024/0188379 A1
(43) Pub. Date: Jun. 6, 2024

(54) DISPLAY PANEL, ELECTRONIC APPARATUS INCLUDING THE SAME AND METHOD OF MANUFACTURING DISPLAY PANEL

(71) Applicant: Samsung Display Co., Ltd., Yongin-si (KR)

(72) Inventors: HYUNEOK SHIN, Yongin-si (KR); JOONYONG PARK, Yongin-si (KR); JUHYUN LEE, Yongin-si (KR)

(73) Assignee: Samsung Display Co., Ltd., Yongin-si (KR)

(21) Appl. No.: 18/468,760

(22) Filed: Sep. 18, 2023

(30) Foreign Application Priority Data
Dec. 5, 2022 (KR) 10-2022-0167501

(51) Int. Cl. H10K 59/80; G02B 27/01; H10K 71/12

(52) U.S. Cl. CPC H10K 59/80518; G02B 27/0172; H10K 59/80524; H10K 71/12; H10K 2102/103

(57) ABSTRACT

A display panel includes a circuit layer including a pixel region and a non-pixel region, a first light-emitting element disposed on the circuit layer; and an inorganic layer disposed on the circuit layer and including a first portion and a second portion, wherein the first light-emitting element includes a first resonance electrode disposed on the circuit layer and including a reflective electrode and a first transparent electrode disposed on the reflective electrode, a light-emitting portion disposed on the first resonance electrode, and an upper electrode disposed on the light-emitting portion, the second portion is disposed between the reflective electrode and the first transparent electrode, at least one opening is defined in the second portion, the first transparent electrode includes a first transparent portion and a second transparent portion, and a first length of the first transparent portion is greater than a second length of the second transparent portion.

### CROSS-REFERENCE TO RELATED APPLICATIONS

This U.S. non-provisional patent application claims priority to and benefits of Korean Patent Application No. 10-2022-0167501 under 35 U.S.C. § 119, filed in the Korean Intellectual Property Office (KIPO) on Dec. 5, 2022, the entire contents of which are hereby incorporated by reference.

### BACKGROUND

The disclosure herein relates to a display panel including a light-emitting layer, an electronic apparatus including the same and a method of manufacturing a display panel, and more specifically, to a display panel including a portion of an inorganic layer in a first electrode, an electronic apparatus including the same, and a method of manufacturing a display panel.

Various types of electronic apparatuses that are wearable on the body are being developed, and these apparatuses are generally referred to as wearable electronic apparatuses. Such a wearable electronic apparatus may have various forms that are attachable/detachable to/from a part of the human body or clothes. Examples of a wearable electronic apparatus may include an apparatus that is attachable to a user's head, and such an apparatus may be called, for example, a head-mounted display (HMD) apparatus. Since an apparatus such as an HMD is disposed close to a user, there is a demand for a method for resolving a screen door effect (SDE) in which pixel-dividing lines are visible to a user.

### SUMMARY

The disclosure provides a display panel having improved display efficiency and display lifespan, an electronic apparatus, and a method of manufacturing a display panel with improved process efficiency.

The technical objectives to be achieved by the disclosure are not limited to those described herein, and other technical objectives that are not mentioned herein would be clearly understood by a person skilled in the art from the description of the disclosure.

An embodiment of the disclosure provides a display panel including a circuit layer including a pixel region and a non-pixel region defined adjacent to the pixel region; a first light-emitting element disposed on the circuit layer and overlapping the pixel region; and an inorganic layer disposed on the circuit layer and including a first portion overlapping the non-pixel region and a second portion extending in a first direction from the first portion and overlapping the pixel region, wherein the first light-emitting element includes a first resonance electrode disposed on the circuit layer and including a reflective electrode and a first transparent electrode disposed on the reflective electrode, a light-emitting portion disposed on the first resonance electrode, and an upper electrode disposed on the light-emitting portion, the second portion is disposed between the reflective electrode and the first transparent electrode, at least one opening is defined in the second portion to expose a portion of an upper surface of the reflective electrode, the first transparent electrode includes a first transparent portion disposed on the second portion and a second transparent portion disposed within the opening, and a first length of the first transparent portion in the first direction is greater than a second length of the second transparent portion in the first direction.

In an embodiment, the first transparent portion may be disposed directly on the second portion.

In an embodiment, the second transparent portion may contact the reflective electrode through the opening.

In an embodiment, the second transparent portion may entirely overlap the side surface of the opening.

In an embodiment, a material included in the first portion and a material included in the second portion may each include at least one of silicon nitride, silicon oxynitride, and silicon oxide.

In an embodiment, the reflective electrode may include at least one of silver (Ag), magnesium (Mg), aluminum (Al), platinum (Pt), lead (Pd), gold (Au), nickel (Ni), neodymium (Nd), iridium (Ir), and chromium (Cr).

In an embodiment, the first transparent electrode may include indium tin oxide (ITO).

In an embodiment, the first resonance electrode may further include an oxidation electrode disposed on the reflective electrode, and the second transparent portion contacts the oxidation electrode through the opening.

In an embodiment, the oxidation electrode may include indium gallium zinc oxide (IGZO).

In an embodiment, the display panel may further include a second light-emitting element spaced apart from the first light-emitting element on a plane and disposed on the circuit layer, wherein the second light-emitting element may include a second resonance electrode having the reflective electrode and a second transparent electrode disposed on the reflective electrode, the light-emitting portion disposed on the second resonance electrode, and the upper electrode.

In an embodiment, a thickness of the second resonance electrode may be smaller than a thickness of the first resonance electrode.

In an embodiment, the second portion may not be disposed between the reflective electrode and the second transparent electrode.

In an embodiment, the first portion may be disposed between the first light-emitting element and the second light-emitting element and divide the first light-emitting element and the second light-emitting element.

In an embodiment, the second resonance electrode may further include an oxidation electrode disposed on the reflective electrode, and a lower surface of the second transparent electrode may entirely overlap an upper surface of the oxidation electrode.

In an embodiment, a pixel opening may be defined in the first portion, and the pixel opening may expose an upper surface of the reflective electrode.

In an embodiment, the display panel may further include a spacer disposed on the first portion and overlapping the non-pixel region.

In an embodiment of the disclosure, a method of manufacturing a display panel, the method including providing a preliminary panel member including a circuit layer having a pixel region and a non-pixel region extending from the pixel region in a first direction and a preliminary resonance electrode which is disposed on the circuit layer and overlaps the pixel region and in which a reflective electrode and an oxidation electrode are sequentially stacked; forming a preliminary inorganic layer on the preliminary panel member to overlap the pixel region and the non-pixel region; forming an inorganic layer by forming, in the preliminary inorganic layer, an opening exposing at least a portion of the oxidation electrode; forming a first transparent electrode in the opening and on the inorganic layer to overlap the pixel region; and forming a light-emitting portion on the first transparent electrode, wherein the first transparent electrode includes a first transparent portion disposed on the inorganic layer and a second transparent portion disposed in the opening, and a first length of the first transparent portion in the first direction is greater than a second length of the second transparent portion in the first direction.

In an embodiment, the forming of the inorganic layer may be performed by a photoresist process.

In an embodiment, the forming of the inorganic layer may include forming a pixel opening spaced apart from the opening on a plane and defined in the inorganic layer, and the first transparent electrode may not be formed on a side surface within the pixel opening but may be formed on a side surface within the opening.

In an embodiment, the method may further include after the forming of the first transparent electrode, forming a spacer disposed on the inorganic layer to overlap the non-pixel region.

In an embodiment of the disclosure, an electronic apparatus including a display panel, and a lens unit facing the display panel, a display panel including a circuit layer including a pixel region and a non-pixel region defined adjacent to the pixel region; a first light-emitting element disposed on the circuit layer and overlapping the pixel region; and an inorganic layer disposed on the circuit layer and including a first portion overlapping the non-pixel region and a second portion extending in a first direction from the first portion and overlapping the pixel region, wherein the first light-emitting element includes a first resonance electrode disposed on the circuit layer and including a reflective electrode and a first transparent electrode disposed on the reflective electrode, a light-emitting portion disposed on the first resonance electrode, and an upper electrode disposed on the light-emitting portion, the second portion is disposed between the reflective electrode and the first transparent electrode, at least one opening is defined in the second portion to expose a portion of an upper surface of the reflective electrode, the first transparent electrode includes a first transparent portion disposed on the second portion and a second transparent portion disposed within the opening, and a first length of the first transparent portion in the first direction is greater than a second length of the second transparent portion in the first direction.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic exploded perspective view illustrating an electronic apparatus according to an embodiment;

FIG. 2A is a schematic perspective view illustrating an electronic apparatus according to an embodiment;

FIG. 2B is a schematic exploded perspective view of an electronic apparatus according to an embodiment;

FIG. 3 is a schematic plan view of a display panel according to an embodiment;

FIG. 4A is a schematic cross-sectional view of a display panel according to an embodiment;

FIG. 4B is a schematic plan view of a display panel according to an embodiment;

FIGS. 5A and 5B are schematic cross-sectional views each illustrating a portion of a display element layer according to another embodiment;

FIGS. 6A and 6B are schematic cross-sectional views each illustrating a light-emitting element according to an embodiment; and

FIGS. 7A to 7E are schematic cross-sectional views each illustrating some operations in a method of manufacturing a display panel according to an embodiment of the disclosure.

### DETAILED DESCRIPTION OF THE EMBODIMENTS

The disclosure may be implemented in various modifications and have various forms and specific embodiments are illustrated in the drawings and described in detail in the text. It is to be understood, however, that the disclosure is not intended to be limited to the particular forms disclosed, but on the contrary, is intended to cover all modifications, equivalents, and alternatives falling within the spirit and scope of the disclosure.

In this specification, it will be understood that when an element (or a region, a layer, a portion, or the like) is referred to as “being on”, “being connected to” or “being coupled to” another element, it may be disposed directly on/connected to/coupled to the other element, or an intervening third element may be also disposed therebetween.

Like reference numerals or characters refer to like elements throughout. Also, in the drawings, the thicknesses, ratios, and dimensions of the elements are exaggerated for an effective description of the technical contents. The term “and/or” includes all of one or more combinations which may be defined by related elements. The phrase “at least one of A and B” may be construed as A only, B only, or any combination of A and B. Also, “at least one of X. Y. and Z” and “at least one selected from the group consisting of X. Y, and Z” may be construed as X only, Y only, Z only, or any combination of two or more of X, Y, and Z.

Although the terms first, second, or the like may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be understood that the term “includes” “comprises,” or “has”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined or implied herein, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display panel and an electronic apparatus including the same according to an embodiment of the disclosure will be described with reference to the drawings.

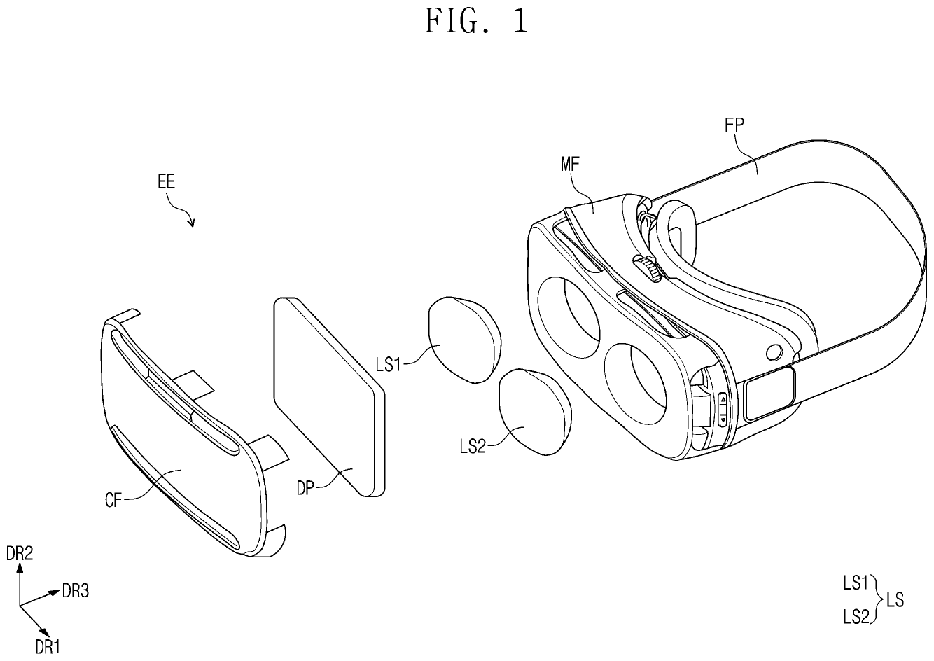

FIG. 1 is a schematic perspective view illustrating an electronic apparatus EE according to an embodiment. The electronic apparatus EE may be an apparatus which is activated in response to an electrical signal. For example, the electronic apparatus EE may be a television, a monitor, an external billboard, a game console, a personal computer, a laptop computer, a mobile phone, a tablet computer, a game console, a navigation system, and a wearable apparatus, but an embodiment of the disclosure is not limited thereto.

FIG. 1 illustrates a head-mounted display (HMD) apparatus as an example of the electronic apparatus EE. The head-mounted display apparatus may be an apparatus mounted on a user's head to provide the user with a screen on which an image or video is displayed. The head-mounted display apparatus may include a see-through type apparatus that provides augmented reality (AR) based on real external objects and a see-closed type apparatus that provides virtual reality (VR) to users on a screen independent of external objects.

Referring to FIG. 1, the electronic apparatus EE may include a display panel DP and a lens part LS facing the display panel DP. Also, the electronic apparatus EE may include a main frame MF, a cover frame CF, and a fixing part FP.

The main frame MF may be a part worn on the user's face. The main frame MF may have a shape corresponding to the shape of the user's head (face). For example, the length of the fixing part FP may be adjusted according to the circumference of the user's head. The fixing part FP is a structure that allows the main frame MF to be readily mounted on the head, and may include a strap, a belt, or the like. However, an embodiment of the disclosure is not limited thereto, and the fixing part FP may have various shapes such as a helmet or an eyeglass temple coupled or connected with the main frame MF.

The lens part LS, the display panel DP, and the cover frame CF may be mounted on the main frame MF. The main frame MF may include a space or structure in which the lens part LS and the display panel DP may be accommodated.

The lens part LS may be disposed between the display panel DP and the user. The lens part LS may allow light emitted from the display panel DP to pass therethrough and may provide the light to the user. For example, the lens part LS may include various types of lenses such as a multi-channel lens, a convex lens, a concave lens, a spherical lens, an aspheric lens, a single lens, a compound lens, a standard lens, a narrow-angle lens, a wide-angle lens, a fixed focus lens, and a variable focus lens.

The lens part LS may include a first lens LS1 and a second lens LS2. The first lens LS1 and the second lens LS2 may be disposed to correspond to positions of the user's left and right eyes. The first lens LS1 and the second lens LS2 may be accommodated inside the main frame MF.

The display panel DP may be provided in a state of being fixed to the main frame MF or may be provided in a detachable manner. The display panel DP will be described in more detail below.

The cover frame CF may be disposed on a surface of the display panel DP to protect the display panel DP. The cover frame CF and the lens part LS may be spaced apart from each other with the display panel DP therebetween.

In FIG. 1 and the following drawings, a first direction DR1 to a third direction DR3 are illustrated. The directions indicated by the first to third directions DR1, DR2, and DR3 illustrated in this specification may have a relative concept and thus be changed to other directions. The directions indicated by the first to third directions DR1, DR2, and DR3 may be referred to as the first to third directions, and may thus be denoted as the same reference numerals or symbols. In this specification, the first direction DR1 and the second direction DR2 may be perpendicular to each other, and the third direction DR3 may be a direction normal to the plane defined by the first direction DR1 and the second direction DR2.

A thickness direction of the electronic apparatus EE may be parallel to the third direction DR3 that is a direction normal to the plane defined by the first direction DR1 and the second direction DR2. In this specification, a front surface (or upper surface) and a rear surface (or lower surface) of each member forming the electronic apparatus EE may be defined based on the third direction DR3. In this specification, “on a plane” means a plane parallel to the plane defined by the first and second directions DR1 and DR2, and “on a cross section” means a plane parallel to the third direction DR3.

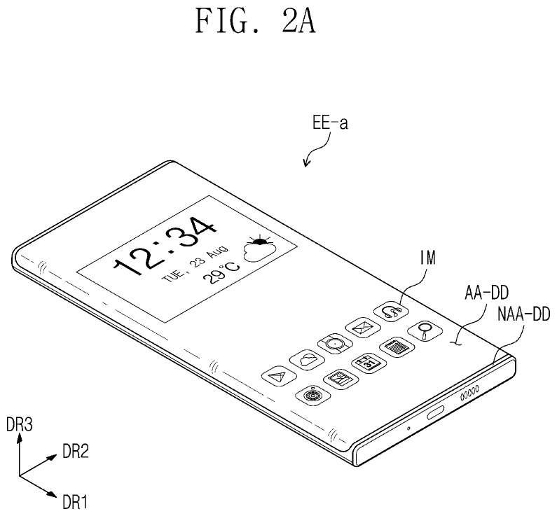

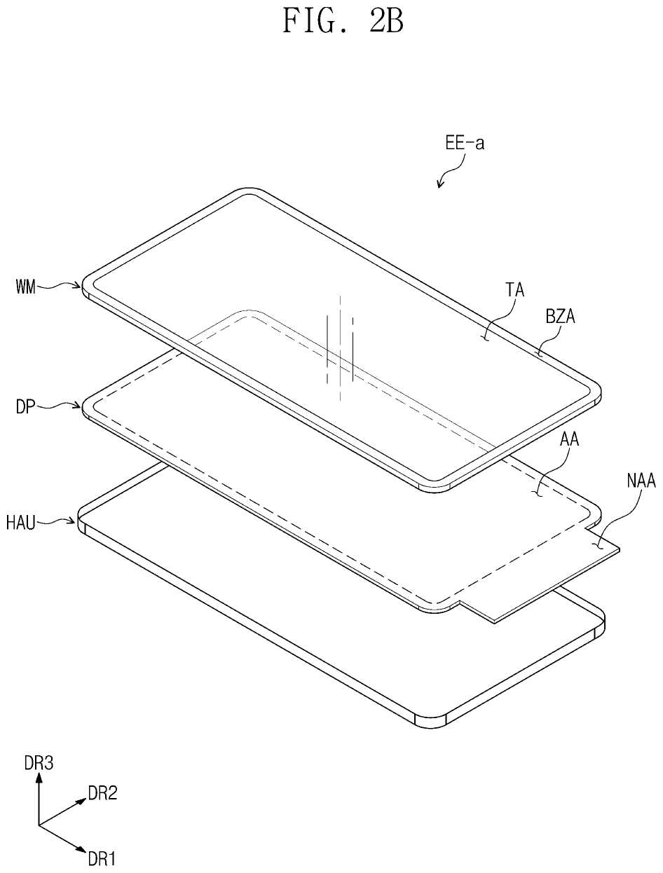

FIG. 2A is a schematic perspective view, of another embodiment of the electronic apparatus according to the disclosure, illustrating a mobile phone as an example of an electronic apparatus EE-a. The electronic apparatus EE-a may display an image IM through an active region AA-DD. The active region AA-DD may include a flat surface defined by a first direction DR1 and a second direction DR2. The active region AA-DD may further include a curved surface that bends from at least one side of the flat surface defined by the first direction DR1 and the second direction DR2. However, this is merely an example, and the shape of the active region AA-DD is not limited thereto. For example, the active region AA-DD may include only the flat surface, or the active region AA-DD may further include four curved surfaces that bend respectively from at least two sides, for example, four sides of the flat surface.

A peripheral region NAA-DD may be adjacent to the active region AA-DD. The peripheral region NAA-DD may surround the active region AA-DD. Accordingly, the shape of the active region AA-DD may be substantially defined by the peripheral region NAA-DD. However, this is illustrated as an example, and the peripheral region NAA-DD may be disposed adjacent to only a side of the active region AA-DD or may be omitted. The active region AA-DD may be provided in various shapes and is not limited to any one embodiment.

FIG. 2B is a schematic exploded perspective view of the electronic apparatus EE-a illustrated in FIG. 2A. Referring to FIG. 2B, the electronic apparatus EE-a may include a housing HAU, a display module DP, and a window member WM.

The window member WM may cover the entire exterior of the display panel DP. The window member WM may include a transmission region TA and a bezel region BZA. The front surface of the window member WM including the transmission region TA and the bezel region BZA may serve as the front surface of the electronic apparatus EE-a. The transmission region TA may correspond to the active region AA-DD of the electronic apparatus EE-a illustrated in FIG. 2A, and the bezel region BZA may correspond to the peripheral region NAA-DD of the electronic apparatus EE-a illustrated in FIG. 2A.

The transmission region TA may be an optically transparent region. The bezel region BZA may be a region having a relatively lower light transmittance than the transmission region TA. The bezel region BZA may have a color (e.g., a predetermined or selectable color). The bezel region BZA may be adjacent to the transmission region TA and may surround the transmission region TA. The bezel region BZA may define a shape of the transmission region TA. However, an embodiment of the disclosure is not limited to those illustrated in the drawing. The bezel region BZA may be disposed adjacent to only a side of the transmission region TA, or a portion thereof may be omitted.

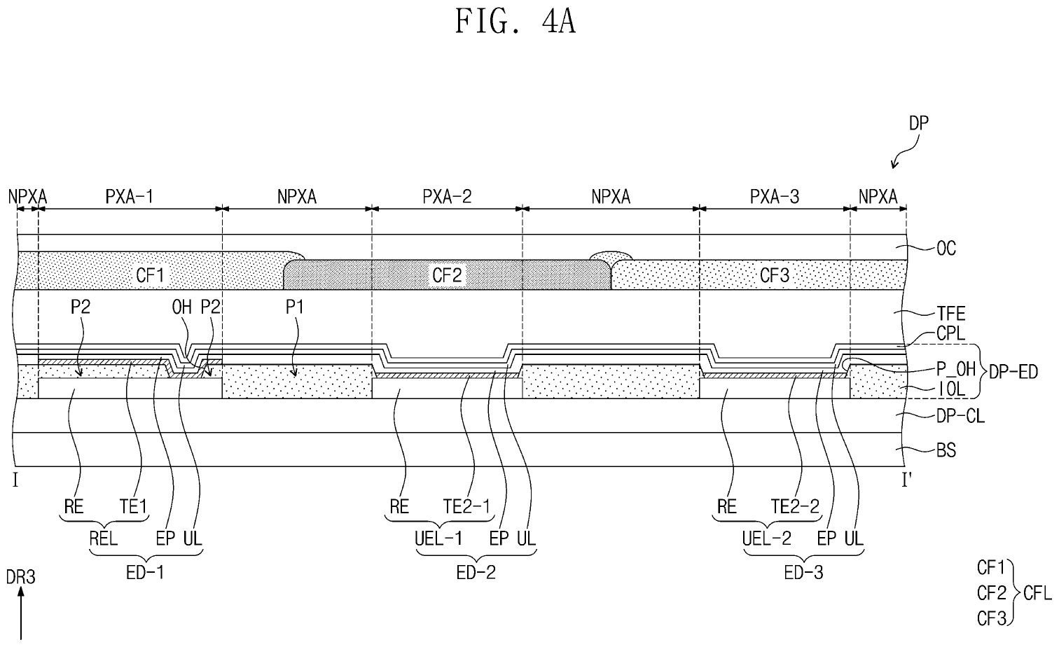

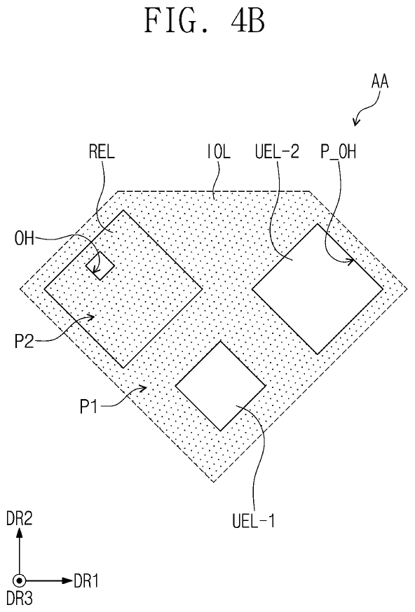

Although not illustrated, an input sensing portion may be provided on the display panel DP. The input sensing portion may sense an external input applied from the outside. The external input may be a user's input. The user's input may include various types of external inputs such as a portion of the user's body, light, heat, a pen, or pressure. More specifically, the input sensing portion (not shown) may be disposed on an encapsulation layer TFE (see FIG. 4A) of the display panel DP, which will be described below. As another example, the input sensing portion (not shown) may be disposed directly on the encapsulation portion TFE (see FIG. 4A) or may be disposed directly on an adhesive member (not shown) disposed on the encapsulation portion TFE (see FIG. 4A). The adhesive member may include a typical adhesive or bonding agent.

In this specification, the wording, “one component (or region, layer, section, etc.) is disposed directly on another component” means that no third component is disposed between the component and the other component. For example, when one component is “directly disposed” on another component, it means that the component and the other component are “contact” each other.

The housing HAU may accommodate the display panel DP and the like. The housing HAU may be coupled to the window member WM.

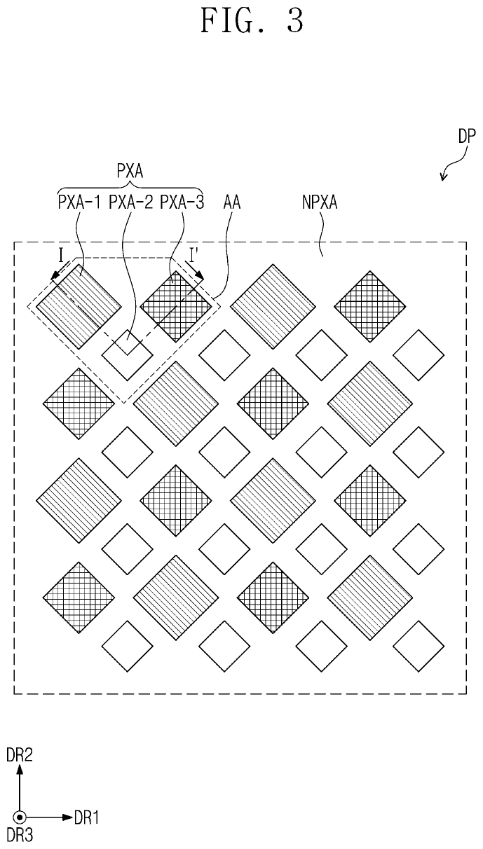

FIG. 3 is a schematic plan view of a display panel DP according to an embodiment. Hereinafter, the description of the display panel DP may be similarly applied to the display panel DP included in the electronic apparatuses EE and EE-a illustrated in FIGS. 1 and 2B.

Referring to FIG. 3, the display panel DP may include a pixel region PXA and a non-pixel region NPXA. The non-pixel region NPXA may surround the pixel region PXA or may be adjacent thereto. The pixel regions PXA may be provided in plurality. The pixel region PXA may include a first pixel region PXA-1, a second pixel region PXA-2, and a third pixel region PXA-3. Each of the first pixel region PXA-1, the second pixel region PXA-2, and the third pixel region PXA-3 may emit light having a different wavelength range. The first pixel region PXA-1 may emit first light, and the second pixel region may emit second light different from the first light. The third pixel region PXA-3 may emit third light different from the first and second light.

Among the first to third pixel regions PXA-1, PXA-2, and PXA-3, the first pixel region PXA-1 may have the largest area, and the second pixel region PXA-2 may have the smallest area. However, this is merely an example, and the areas of the first to third pixel regions PXA-1, PXA-2, and PXA-3 are not limited thereto. In FIG. 3, the first pixel region PXA-1 and the third pixel region PXA-3 may be alternately arranged in a row, and the second pixel region PXA-2 may be spaced apart from the first pixel region PXA-1 and the third pixel region PXA-3, and may be arranged in a different row. However, this is merely an example, and the arrangement of the first to third pixel regions PXA-1, PXA-2 and PXA-3 is not limited thereto.

FIG. 4A is a schematic cross-sectional view taken along line I-I′ of FIG. 3 and may be a schematic cross-sectional view of the display panel DP according to an embodiment. FIG. 4B is a schematic view illustrating a portion corresponding to region AA of FIG. 3. For the convenience of description, only first electrodes REL, UEL-1, and UEL-2 and an inorganic layer IOL are illustrated in FIG. 4B.

Referring to FIG. 4A, the display panel DP may include a base layer BS, a circuit layer DP-CL disposed on the base layer BS, a display element layer DP-ED disposed on the circuit layer DP-CL, and/or an encapsulation layer TFE disposed on the display element layer DP-ED. The display panel DP may further include a color filter layer CFL disposed on the encapsulation layer TFE.

The base layer BS may be a member that provides a base surface on which the circuit layer DP-CL is disposed. The base layer BS may be a rigid substrate or a flexible substrate capable of bending, folding, rolling, or the like. The base layer BS may be, e.g., a glass substrate, a metal substrate, or a polymer substrate. However, an embodiment is not limited thereto, and the base layer BS may be an inorganic layer, an organic layer, or a composite layer.

The base layer BS may include a single- or multi-layered structure. For example, the base layer BS may include at least one of a first synthetic resin layer, an intermediate layer having a multi- or single-layer structure, and a second synthetic resin layer which are sequentially stacked each other. The intermediate layer may be referred to as a base barrier layer. The intermediate layer may include a silicon oxide (SiOx) layer and an amorphous silicon (a-Si) layer disposed on the silicon oxide layer, but is not particularly limited thereto. For example, the intermediate layer may include at least one of a silicon oxide layer, a silicon nitride layer, a silicon oxynitride layer, or an amorphous silicon layer.

Each of the first and second synthetic resin layers may include a polyimide-based resin. Each of the first and second synthetic resin layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, an “X-based” resin may be considered as including a functional group of “X”.

The circuit layer DP-CL may be disposed on the base layer BS. The circuit layer DP-CL may include an insulating layer, a semiconductor pattern, a conductive pattern, a signal line, and the like. The insulating layer, the semiconductor layer, and the conductive layer may be formed on the base layer BS through coating, deposition, or the like, and the insulating layer, the semiconductor layer, and the conductive layer may be selectively patterned by performing a photolithography process multiple times. The semiconductor pattern, the conductive pattern, and the signal line which are included in the circuit layer DP-CL may be formed.

The display element layer DP-ED may be disposed on the circuit layer DP-CL. The display element layer DP-ED may include first to third light-emitting elements ED-1, ED-2, and ED-3, a capping layer CPL and an inorganic layer IOL.

Referring to FIGS. 4A and 4B, the first to third light-emitting elements ED-1, ED-2, and ED-3 may be spaced apart from each other in a direction perpendicular to the thickness direction DR3. Each of the first to third light-emitting elements ED-1, ED-2, and ED-3 may include the first electrodes REL, UEL-1, and UEL-2, a light-emitting portion EP disposed on the first electrodes REL, UEL-1, and UEL-2, and a second electrode UL disposed on the light-emitting portion EP.

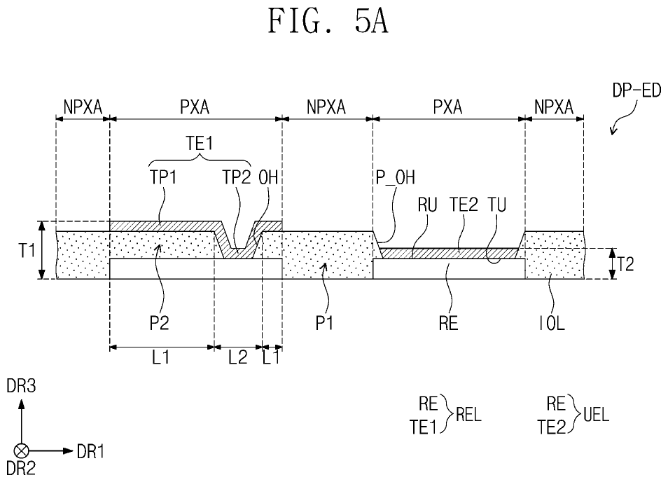

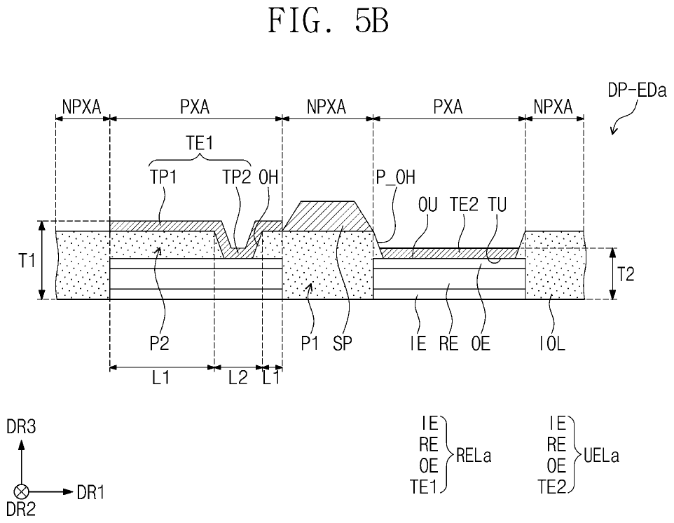

The first electrodes REL, UEL-1, and UEL-2 may include a reflective electrode RE and transparent electrodes TE1, TE2-1, and TE2-2 disposed on the reflective electrode RE. The first electrodes REL, UEL-1, and UEL-2 according to this embodiment may include a first resonance electrode REL and/or second resonance electrodes UEL-1 and UEL-2 according to the corresponding light-emitting elements ED-1, ED-2, and ED-3. For example, the first light-emitting element ED-1 may include the first resonance electrode REL, and the second light-emitting element ED-2 and the third light-emitting element ED-3 may respectively include the second resonance electrodes UEL-1 and UEL-2. However, the first electrode of the light-emitting elements ED-1, ED-2, and ED-3 of the disclosure is not limited to the above example, and the first resonance electrode REL and the second resonance electrodes UEL-1 and UEL-2 may be arranged in various ways, if necessary, according to designing in consideration of the degree of resonance in each light-emitting element ED-1. ED-2, and ED-3. For example, each of the first light-emitting element ED-1 and the second light-emitting element ED-2 may include the first resonance electrode, and the third light-emitting element ED-3 may include the second resonance electrode. A detailed description of the first resonance electrode REL and the second resonance electrodes UEL-1 and UEL-2 will be described in detail with reference to FIGS. 5A and 5B.

In the first to third light-emitting elements ED-1, ED-2, and ED-3, the light-emitting portion EP may be provided as a common layer. The first to third light-emitting elements ED-1, ED-2, and ED-3 may have a tandem structure. The light-emitting portion EP may overlap the first to third pixel regions PXA-1, PXA-2, and PXA-3 and the non-pixel region NPXA. In this specification, the wording, “one component and another component overlapping each other” is not limited to the element and the other element having the same planar shape and the same planar area, and also means the cases of having different areas and/or different shapes. Unlike what is illustrated, in an embodiment, the light-emitting portion EP may be disposed within a pixel opening P_OH defined by a first portion P1 to be described below, and may be provided to correspond to the first to third pixel regions PXA-1. PXA-2, and PXA-3.

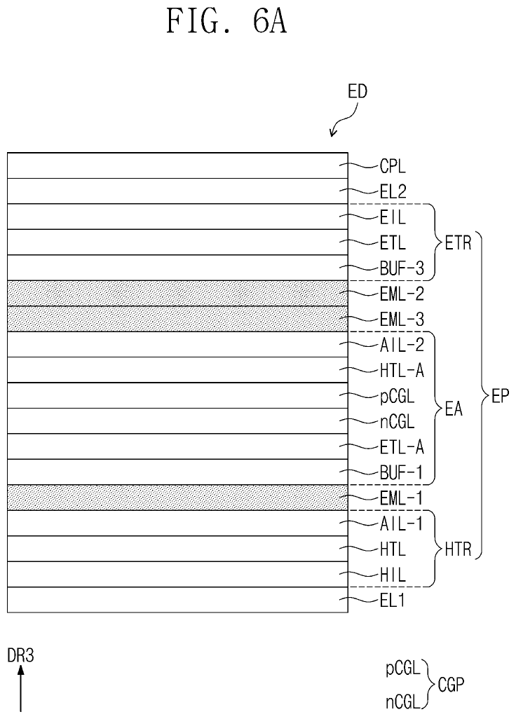

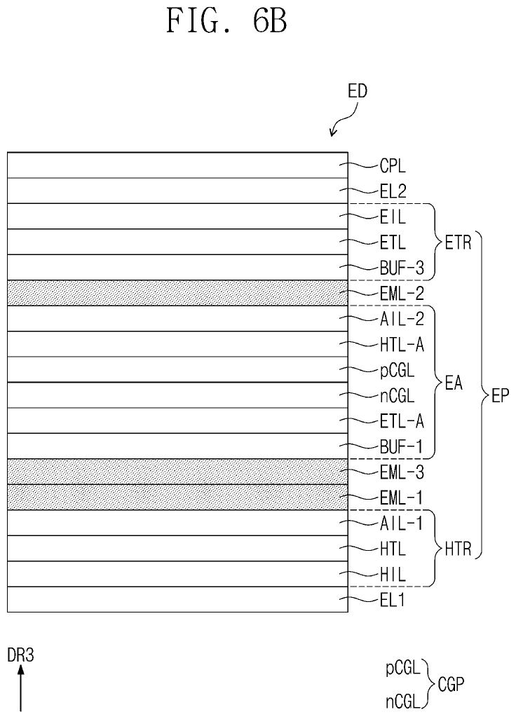

The light-emitting portion EP may include at least light-emitting layers EML-1. EML-2, and EML-3 (see FIG. 6A). The light-emitting portion EP will be described in detail below.

In the first to third light-emitting elements ED-1, ED-2, and ED-3, the second electrode UL may be provided as a common electrode. In this specification, the second electrode UL disposed on the light-emitting portion EP may mean an “upper electrode”.

In the display element layer DP-ED, the inorganic layer IOL may be a structure disposed directly on the circuit layer DP-CL. In an embodiment, the inorganic layer IOL may include the first portion P1 and a second portion P2.

The pixel opening P_OH may be defined in the first portion P1. The first portion P1 may perform a function to define the pixel. For example, each of the first to third pixel regions PXA-1, PXA-2, and PXA-3 may be a region divided by the first portion P1. The non-pixel regions NPXA may be regions provided between the neighboring first to third pixel regions PXA-1, PXA-2, and PXA-3, and corresponding to the first portion P1. The first portion P1 may be disposed between the light-emitting elements ED-1, ED-2, and ED-3 to distinguish the light-emitting elements ED-1, ED-2, and ED-3.

The second portion P2 may be a portion extending from the first portion P1 in the first direction DR1. For example, the first portion P1 and the second portion P2 may be regions adjacent to each other in the first direction DR1. An opening OH may be defined in the second portion P2. In an embodiment, the second portion P2 may be disposed within the first electrode REL. The first portion P1 and the second portion P2 will be described in detail below.

The encapsulation layer TFE may be disposed on the display element layer DP-ED. The encapsulation layer TFE may protect the display element layer DP-ED from foreign substances such as moisture, oxygen, and dust particles. The encapsulation layer TFE may include at least one inorganic film (hereinafter referred to as an inorganic encapsulation film). The encapsulation layer TFE may include at least one organic film (hereinafter referred to as an organic encapsulation film) and at least one inorganic encapsulation film.

The inorganic encapsulation film may protect the display element layer DP-ED from moisture or oxygen, and the organic encapsulation film may protect the display element layer DP-ED from foreign substances such as dust particles. The inorganic encapsulation film may include, e.g., at least one of silicon nitride, silicon oxynitride, silicon oxide, titanium oxide, and aluminum oxide, but an embodiment of the disclosure is not limited thereto. The organic encapsulation film may include, e.g., at least one of an acrylic-based compound, an epoxy-based compound, and the like. The organic encapsulation film may include a photopolymerizable organic material and is not particularly limited.

The color filter layer CFL may be disposed on the encapsulation layer TFE. The color filter layer CFL may include a first filter CF1 corresponding to the first pixel region PXA-1, a second filter CF2 corresponding to the second pixel region PXA-2, and a third filter CF3 corresponding to the third pixel region PXA-3. Although not illustrated, the color filter layer CFL may further include a light blocking portion (not shown). The light blocking portion may be a black matrix. The light blocking portion may be formed including an organic light blocking material or an inorganic light blocking material which contains a black pigment or a black dye. The light blocking portion may prevent a light leakage phenomenon and define boundaries between adjacent filters CF1, CF2, and CF3.

Each of the first to third filters CF1, CF2, and CF3 may include a polymer photosensitive resin and a colorant. In this specification, the colorant may contain pigments and dyes. A red colorant may contain a red pigment and a red dye, a green colorant may contain a green pigment and a green dye, and a blue colorant may contain a blue pigment and a blue dyc.

In FIG. 4A, a first filter CF1 may include a blue pigment or a blue dye, the second filter CF2 may include a green pigment or a green dye, and the third filter CF3 may include a red pigment or a red dye. For example, the first filter CF1 which is disposed on the first light-emitting element ED-1 including the first resonance electrode REL may contain a blue colorant. The second filter which is disposed on the second light-emitting element ED-2 not including the first resonance electrode REL may contain a green colorant, and a third filter which is disposed on the third light-emitting element ED-3 not including the first resonance electrode REL may contain a red colorant. On the other hand, the first filter CF1 which is disposed on the first light-emitting element ED-1 including the first resonance electrode REL may contain a green colorant, the second filter disposed on the second light-emitting element ED-2 not including the first resonance electrode REL may contain a red colorant, and the third filter which is disposed on the third light-emitting element ED-3 not including the first resonance electrode REL may contain a blue colorant. A layer OC may be disposed on the first, second, and third filters CF1, CF2, and CF3.

FIGS. 5A and 5B are schematic cross-sectional views each illustrating a portion of a display element layer according to another embodiment. FIGS. 5A and 5B illustrate the first electrodes REL and UEL and the inorganic layer IOL in the display element layer DP-ED in more detail.

Referring to FIGS. 5A and 5B, the display element layers DP-ED and DP-EDa according to an embodiment may include first electrodes REL, RELa, UEL, and UELa and an inorganic layer IOL.

Referring to FIG. 5A, the first electrodes REL and UEL according to an embodiment of the disclosure may include a reflective electrode RE and transparent electrodes TE1 and TE2. Referring to FIG. 5B, the first electrodes RELa and UELa according to an embodiment may include a lower oxidation electrode IE, a reflective electrode RE, an oxidation electrode OE, and transparent electrodes TE1 and TE2.

The lower oxidation electrode IE, the oxidation electrode OE, and the transparent electrodes TE1 and TE2 may each include a transparent conductive film. For example, the lower oxidation electrode IE, the oxidation electrode OE, and the transparent electrodes TE1 and TE2 may each include at least one selected from the group consisting of indium tin oxide (ITO), indium zinc oxide (IZO), indium gallium zinc oxide (IGZO), zinc oxide (ZnOx), or indium oxide (In₂O₃), and aluminum doped zinc oxide (AZO). For example, the lower oxidation electrode IE and the transparent electrodes TE1 and TE2 may each include indium tin oxide (ITO). The oxidation electrode OE may include indium gallium zinc oxide (IGZO). Accordingly, in manufacturing a display panel according to an embodiment of the disclosure, an excellent or desired etching rate may be ensured when forming the opening OH or the pixel opening P_OH in the inorganic layer IOL.

The reflective electrode RE may include, e.g., at least one of Ag, Mg, Cu, Al, Pt, Pd, Au, Ni, Nd, Ir. Cr. Li, Ca, LiF/Ca, LiF/Al, Mo, and Ti having high reflectivity. For example, the reflective electrode RE may include Ag.

Referring to FIGS. 5A and 5B, in an embodiment, the first electrodes REL, RELa. UEL, and UELa may be the first resonance electrodes REL and RELa or the second resonance electrodes UEL and UELa. The first resonance electrodes REL and RELa may include the reflective electrode RE and a first transparent electrode TE1 disposed on the reflective electrode RE. The second resonance electrodes UEL and UELa may include the reflective electrode RE and a second transparent electrode TE2 disposed on the reflective electrode RE.

Referring to FIG. 5B, the first resonance electrode RELa may have a structure in which a lower oxidation electrode IE, a reflective electrode RE, an oxidation electrode OE, and a first transparent electrode TE1 are sequentially stacked each other. The second resonance electrode UELa may have a structure in which the lower oxidation electrode IE, the reflective electrode RE, the oxidation electrode OE, and the second transparent electrode TE2 are sequentially stacked each other.

Referring to FIGS. 5A and 5B, in an embodiment, the inorganic layer IOL may include a first portion P1 and a second portion P2. The first portion P1 may be disposed directly on the display element layer DP-CL (see FIG. 4A). At least a portion of the first portion P1 may overlap the non-pixel region NPXA. The pixel opening P_OH may be defined in the first portion P1.

The second transparent electrode TE2 of the second resonance electrode UEL may be disposed in the pixel opening P_OH. The pixel opening P_OH may expose at least a portion of the second resonance electrode UEL. The pixel opening P_OH may expose at least a portion of the reflective electrode RE of the second resonance electrode UEL. The pixel opening P_OH may expose at least a portion of the oxidation electrode OE of the second resonance electrode UEL. For example, the pixel opening P_OH may expose about 70% or more of an upper surface OU of the oxidation electrode OE or an upper surface RU of the reflective electrode RE of the second resonance electrode UEL.

The second transparent electrode TE2 of the second resonance electrode UEL may be disposed on (or directly on) the exposed upper surface RU of the reflective electrode RE or the exposed upper surface OU of the oxidation electrode OE. The lower surface TU of the second transparent electrode TE2 may overlap (or entirely overlap) the upper surface RU of the reflective electrode RE or the upper surface OU of the oxidation electrode OE. The second transparent electrode TE2 may not be disposed on a side surface of the pixel opening P_OH. Accordingly, in the second resonance electrode UEL, another member may not be disposed between the second transparent electrode TE2 and the reflective electrode RE or between the second transparent electrode TE2 and the oxidation electrode OE. For example, referring to FIG. 5A, in the second resonance electrode UEL, the second portion P2 may not be disposed between the second transparent electrode TE2 and the reflective electrode RE. As another example, referring to FIG. 5B, the second portion P2 may not be disposed between the second transparent electrode TE2 and the oxidation electrode OE in the second resonance electrode UELa.

The second portion P2 may overlap the pixel region PXA. The second portion P2 may be defined as a portion of the inorganic layer IOL disposed between the first transparent electrode TE1 and the reflective electrode RE of the first resonance electrodes REL and RELa. The second portion P2 may be disposed directly on the oxidation electrode OE of the first resonance electrodes REL and RELa. The opening OH may be defined in the second portion P2. A portion of the first transparent electrode TE1 may be disposed within the opening OH. The opening OH may expose a portion of the first resonance electrodes REL and RELa. The opening OH may expose a portion of the upper surface OU of the oxidation electrode OE. For example, the opening OH may expose about 30% or less of the upper surface RU of the reflective electrode RE or the upper surface OU of the oxidation electrode OE. Accordingly, the second portion P2 may be disposed within the first resonance electrode REL such that the second portion P2 occupies an area greater than about 70% of the total area of the first resonance electrode REL. As the second portion P2 is disposed in the first resonance electrode REL, a separation distance between the second electrode UL and the reflective electrode RE of the first resonance electrode REL may increase.

As the second portion P2 may be disposed within the first resonance electrode REL, the thickness T1 of the first resonance electrode REL and RELa may be greater than the thickness T2 of the second resonance electrode UEL and UELa. The thickness T1 of the first resonance electrode REL and RELa may correspond to a vertical distance from the lowermost surface of the first resonance electrodes REL and RELa to the uppermost surface of the first resonance electrodes REL and RELa in the third direction DR3. In an embodiment, the thickness T1 of the first resonance electrode REL may correspond to a vertical distance from the lower surface of the reflective electrode RE to the upper surface of the first transparent electrode TE1. In another embodiment, the thickness T1 of the first resonance electrode RELa may correspond to a vertical distance from the lower surface of the lower oxidation electrode IE to the upper surface of the first transparent electrode TE1. The thickness T2 of the second resonance electrode UEL and UELa may correspond to a vertical distance from the lowermost surface of the second resonance electrode UEL and UELa to the uppermost surface of the second resonance electrode UEL and UELa in the third direction DR3. In an embodiment, the thickness T2 of the second resonance electrode UEL may correspond to a vertical distance from the lower surface of the reflective electrode RE to the upper surface of the second transparent electrode TE2. In another embodiment, the thickness T2 of the second resonance electrode UELa may correspond to a vertical distance from the lower surface of the lower oxidation electrode IE to the upper surface of the second transparent electrode TE2.

Referring to FIGS. 4A and 5B, as the thickness T1 of the first resonance electrode REL is greater than the thickness T2 of the second resonance electrode UEL, the maximum value of the separation distance between the reflective electrode RE of the first resonance electrode REL and the second electrode UL may be greater than the maximum value of the separation distance between the reflective electrode RE of the second resonance electrode UEL and the second electrode UL. Accordingly, the display panel according to an embodiment of the disclosure may be arbitrarily designed to generate an optimal resonance frequency that causes optical resonance of a specific wavelength in the light-emitting elements ED-1, ED-2, and ED-3. For example, in case that the second portion P2 is disposed in the first resonance electrode REL of the first light-emitting element ED-1, the blue light output by the first light-emitting element ED-1 and the first filter CF1 may be secondarily resonated, and the red or green light output by the second and third light-emitting elements ED-2 and ED-3 and the second and third filters CF2 and CF3 may be primarily resonated. Accordingly, the display panel DP according to an embodiment may exhibit excellent display resolution and improved display lifespan.

Referring to FIGS. 5A and 5B, in the first resonance electrode REL and RELa, the first transparent electrode TE1 may include a first transparent portion TP1 and a second transparent portion TP2. The first transparent portion TP1 may be disposed on the second portion P2. The first transparent portion TP1 may be disposed directly on the upper surface of the second portion P2 and may be disposed entirely on the second portion P2. The first transparent portion TP1 may include portions spaced apart from each other by the second transparent portion TP2 in the first direction DR1 or the second direction DR2. As the first resonance electrode REL and RELa includes the first transparent portion TP1 disposed on the second portion P2, the thickness T1 of the first resonance electrode REL and RELa may be greater than the thickness T2 of the second resonance electrode UEL and UELa.

The second transparent portion TP2 may be disposed within the opening OH. The second transparent portion TP2 may be disposed on a lower surface of the opening OH and a side surface of the opening OH. For example, the second transparent portion TP2 may be disposed on the upper surface RU of the reflective electrode RE and the side surface of the second portion P2. As another example, the second transparent portion TP2 may be disposed on the upper surface OU of the oxidation electrode OE and the side surface of the second portion P2. A portion of the second transparent portion TP2 may be disposed directly on the upper surface RU of the reflective electrode RE or the upper surface OU of the oxidation electrode OE. Since the second portion P2 containing an inorganic material is disposed directly on the reflective electrode RE or the oxidation electrode OE, the second transparent portion TP2 may contact the reflective electrode RE or the oxidation electrode OE in order to provide charges to a hole transport region HTR (see FIG. 6A). The second transparent portion TP2 may contact the reflective electrode RE or the oxidation electrode OE through the opening OH.

In the first transparent electrode TE1 according to an embodiment, the first length L1 of the first transparent portion TP1 is greater than the second length L2 of the second transparent portion TP2. The first length L1 may mean a horizontal length of the first transparent portion TP1 in the first direction DR1. In case that the first transparent portion TP1 includes portions spaced apart from each other by the second transparent portion TP2 in the first direction DR1, the first length L1 may correspond to the sum of the lengths of the respective portions in the first direction DR1. The second length L2 may correspond to the maximum value of the horizontal length of the second transparent portion TP2 in the first direction DR1. Since the second transparent portion TP2 means the first transparent electrode TE1 disposed in the opening OH, the second length L2 may substantially correspond to a maximum value of a horizontal length of the opening OH in the first direction DR1. The sum of the first length L1 and the second length L2 may be substantially equal to the length value of the first transparent electrode TE1.

The inorganic layer IOL including the first portion P1 and the second portion P2 may be formed of (or include), e.g., a silicon-containing inorganic material. In an embodiment, the first portion P1 and the second portion P2 may each include at least one of silicon oxide, silicon oxynitride, or silicon nitride. As the second portion P2 may be formed of the silicon-containing inorganic material, the luminous efficiency of the display panel according to an embodiment of the disclosure may be increased. The extinction coefficient of the silicon-containing inorganic material may have a relatively lower than the extinction coefficient of transparent electrode materials such as indium tin oxide (ITO), indium zinc oxide (IZO), and indium gallium zinc oxide (IGZO), or a combination thereof. Accordingly, compared to the case where a specific functional layer is formed of indium oxide or the like to design the optical resonance in a light-emitting element, the display panel according to the disclosure may achieve a relatively high luminous efficiency.

Referring to FIG. 5B, the display element layer DP-EDa according to an embodiment may further include a spacer SP. The spacer SP may overlap the non-pixel region NPXA and may be disposed on the first portion P1. The spacer SP may be disposed to entirely overlap the non-pixel region NPXA.

FIGS. 6A and 6B are schematic cross-sectional views each illustrating a light-emitting element according to an embodiment. FIGS. 6A and 6B specifically illustrate the light-emitting portion EP according to the disclosure. Description of the light-emitting elements to be described below with reference to FIGS. 6A and 6B may be similarly applied to each of the first to third light-emitting elements ED-1, ED-2, and ED-3 in FIG. 4A.

Referring to FIGS. 6A and 6B, the light-emitting portion EP according to an embodiment may include a hole transport region HTR, a first light-emitting layer EML-1, a light-emitting auxiliary portion EA, a second light-emitting layer EML-2, a third light-emitting layer EML-3, and an electron transport region ETR. In the light-emitting element ED, the hole transport region HTR, the first light-emitting layer EML-1, the light-emitting auxiliary portion EA, the second light-emitting layer EML-2, the third light-emitting layer EML-3, and the electron transport region ETR may be provided as common layers. A light-emitting element ED including the first light-emitting layer EML-1, the second light-emitting layer EML-2, and the third light-emitting layer EML-3 that generate light in different wavelength ranges may emit white light. In an embodiment, the hole transport region HTR, the light-emitting auxiliary portion EA, and an electron transport region ETR which are included in the light-emitting element ED, and the second portion P2 may be provided to have respective thicknesses so that red light, green light, or blue light undergoes nth-order resonance.

Since the first to third light-emitting layers EML-1, EML-2, and EML-3 provided as common layers may be deposited without a mask, a pixel having a smaller area may be formed. In the display panel DP according to an embodiment, a large number of small-area pixels may be disposed on a plane, so that high resolution may be achieved.

In the light-emitting element ED, the hole transport region HTR may be provided on a first electrode EL1. The first electrode EL1 in FIGS. 6A and 6B may mean the first electrodes REL and UEL above-described in FIGS. 4A, 5A, and 5B. The hole transport region HTR may have a single layer formed of a single material, a single layer formed of multiple different materials, or a multi-layered structure that has layers formed of multiple different materials. For example, the hole transport region HTR may include at least one of a phthalocyanine compound such as copper phthalocyanine, N1.N1′-([1,l′-biphenyl]-4,4′-diyl)bis(N1-phenyl-N4,N4-di-m-tolylbenzene-1,4-diamine) (DNTPD), 4.4′,4″-[tris(3-methylphenyl)phenylamino]triphenylamine (m-MTDATA), 4,4′,4″-tris(N,N-diphenylamino)triphenylamine (TDATA), 4.4′0.4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), polyetherketone-containing triphenylamine (TPAPEK), 4-isopropyl-4′-methyldiphenyliodonium[tetrakis(pentafluorophenyl)borate], dipyrazino[2,3-f:2′,3′-h]quinoxaline-2,3,6,7,10,11-hexacarbonitrile (HATCN), or the like, or a combination thereof.

The hole transport region HTR may include, e.g., a carbazole-based derivative such as N-phenylcarbazole and polyvinylcarbazole, a fluorene-based derivative, N,N′-bis(3-methylphenyl)-N,N′-diphenyl-[1,l′-biphenyl]-4,4′-diamine (TPD), a triphenylamine derivative such as 4,4′,4″-tris(N-carbazolyl)triphenylamine (TCTA), 4,4 ‘-cyclohexylidene bis[N,N-bis(4-methylphenyl)benzenamine](TAPC), 4,4’-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), or 1,3-bis(1,8-dimethyl-9H-carbazol-9-yl)benzene (mDCP), or the like, or a combination thereof.

In addition to the above-described materials, the hole transport region HTR may further include a charge generation material to improve conductivity. The charge generation material may be uniformly or non-uniformly dispersed within the hole transport region HTR. The charge generation material may be, for example, a p-dopant. The p-dopant may include at least one of a metal halide compound, a quinone derivative, a metal oxide, or a cyano group-containing compound, but is not limited thereto. For example, the p-dopant may include a metal halide compound such as Cul and RbI, a quinone derivative such as tetracyanoquinodimethane (TCNQ) and 2,3,5,6-tetrafluoro-7,7′8,8-tetracyanoquinodimethane (F4-TCNQ), a metal oxide such as tungsten oxide and molybdenum oxide, dipyrazino[2,3-f:2′,3′-h]quinoxaline-2,3,6,7,10,11-hexacarbonitrile (HATCN), a cyano group-containing compound such as NDP9 (4-[[2,3-bis[cyano-(4-cyano-2,3,5,6-tetrafluorophenyl)methylidene|cyclopropylidene]-cyanomethyl]-2,3,5,6-tetrafluorobenzonitrile), or the like, or a combination thereof, but an embodiment of the disclosure is not limited thereto.

The hole transport region HTR may include a hole injection layer HIL, a first hole transport layer HTL, and a first sub-hole control layer AIL-1 which are sequentially stacked each other. Unlike what is illustrated, at least one of the hole injection layer HIL, the first hole transport layer HTL, and the first sub-hole control layer AIL-1 may be omitted. The hole injection layer HIL, the first hole transport layer HTL, and the first sub-hole control layer AIL-1 may include the above-described compounds of the hole transport region HTR.

The first sub-hole control layer AIL-1 may be disposed adjacent to the first light-emitting layer EML-1 generating the first light. The first sub-hole control layer AIL-1 may be formed to have the highest occupied molecular orbital (HOMO) energy level and the lowest unoccupied molecular orbital (LUMO) energy level in which holes may readily move. Accordingly, an increase in the driving voltage of the light-emitting element ED including the first sub-hole control layer AIL-1 may be prevented. Also, the first sub-hole control layer AIL-1 may block electrons moving from the first light-emitting layer EML-1 to the hole transport region HTR. Therefore, the display panel DP including the light-emitting element ED including the first sub-hole control layer AIL-1 may have an improved display lifespan.

The electron transport region ETR may be provided on the light-emitting auxiliary portion EA. The electron transport region ETR may have a single layer formed of a single material, a single layer formed of multiple different materials, or a multi-layered structure that has layers formed of multiple different materials.

For example, the electron transport region ETR may include an anthracene-based compound. However, an embodiment of the disclosure is not limited thereto, and the electron transport region ETR may include, e.g., Alq₃(tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,l′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and a mixture thereof.

The electron transport region ETR may include a metal halide such as LiF, NaCl, CsF. RbCI, RbI, Cul, and KI, a lanthanum group metal such as Yb, or a co-deposition material of the above-described metal halide and lanthanum group metal, or a combination thereof. For example, the electron transport region ETR may include KI:Yb, RbI: Yb, LiF: Yb, or the like as a co-deposition material. A metal oxide such as Li₂O and BaO, or 8-hydroxyl-lithium quinolate (Liq) may be used for the electron transport region ETR, but an embodiment of the disclosure is not limited thereto. The electron transport region ETR may also be formed of a material in which an electron transport material and an insulating organo metal salt are mixed. The organo metal salt may be a material having an energy band gap of about 4 eV or more. For example, the organo metal salt may include metal acetate, metal benzoate, metal acetoacetate, metal acetylacetonate, or metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but an embodiment of the disclosure is not limited thereto.

The electron transport region ETR may include a first buffer layer BUF-3, a first electron transport layer ETL, and an electron injection layer EIL which are sequentially stacked each other. Unlike what is illustrated, at least one of the first buffer layer BUF-3, the first electron transport layer ETL, and the electron injection layer EIL may be omitted. The first buffer layer BUF-3, the first electron transport layer ETL, and the electron injection layer EIL may include the above-described compounds of the electron transport region ETR. The first buffer layer BUF-3 may block holes moving from the third light-emitting layer EML-3 to the electron transport region ETR.

The light-emitting auxiliary portion EA disposed between the first light-emitting layer EML-1 and the second light-emitting layer EML-2 may include a first auxiliary buffer layer BUF-1, a second electron transport layer ETL-A, a first charge generation layer nCGL, a second charge generation layer pCGL, and a second hole transport layer HTL-A, and a second sub-hole control layer AIL-2 which are sequentially stacked each other. The first charge generation layer nCGL may be an n-type charge generation layer, and the second charge generation layer pCGL may be a p-type charge generation layer. Unlike what is illustrated, at least one of the first auxiliary buffer layer BUF-1, the second electron transport layer ETL-A, the first charge generation layer nCGL, the second charge generation layer pCGL, the second hole transport layer HTL-A, and the second sub-hole control layer AIL-2 may be omitted.

The second sub-hole control layer AIL-2 may include a material different from that of the above-described first sub-hole control layer AIL-1. The second sub-hole control layer AIL-2 may include a material that helps the second light-emitting layer EML-2 to generate the second light or a material that helps the third light-emitting layer EML-3 to generate the third light. The first sub-hole control layer AIL-1 may include a material that helps the first light-emitting layer EML-1 to generate the first light. However, an embodiment of the disclosure is not limited thereto, and the first sub-hole control layer AIL-1 and the second sub-hole control layer AIL-2 may include a same material.

The second sub-hole control layer AIL-2 may be disposed adjacent to the third light-emitting layer EML-3 that generates third light or the second light-emitting layer EML-2 that generates second light. The second sub-hole control layer AIL-2 may be formed to have the highest occupied molecular orbital (HOMO) energy level and the lowest unoccupied molecular orbital (LUMO) energy level in which holes may readily move. Accordingly, an increase in the driving voltage of the light-emitting element ED including the second sub-hole control layer AIL-2 may be prevented. Also, the second sub-hole control layer AIL-2 may block electrons moving from the second light-emitting layer EML-2 or the third light-emitting layer EML-3 to the second hole transport layer HTL-A. Therefore, the display panel DP including the light-emitting element ED having the second sub-hole control layer AIL-2 may have an improved display lifespan.

The second electrode UL (or EL2) may be provided on the electron transport region ETR. The second electrode UL may be a common electrode. The second electrode UL may be a cathode or anode, but an embodiment of the disclosure is not limited thereto. For example, the first electrodes REL, UEL-1, and UEL-2 may be anodes, and the second electrode UL may be a cathode. In contrast, the first electrodes REL, UEL-1, and UEL-2 may be cathodes, and the second electrode UL may be an anode.

The second electrode UL may include at least one selected from Ag. Mg, Cu, Al. Pt, Pd, Au, Ni, Nd, Ir, Cr, Li, Ca, LiF, Mo, Ti, W, In, Sn, and Zn, two or more compounds selected from thereamong, a mixture of two or more selected from thereamong, or oxides thereof. The second electrode UL may be a transmissive electrode, a transflective electrode, or a reflective electrode. In case that the second electrode UL is a transmissive electrode, the second electrode UL may be made of (or include), e.g., a transparent metal oxide, for example, indium tin oxide (ITO), indium zinc oxide (IZO), zinc oxide (ZnO), indium tin zinc oxide (ITZO), or the like, or a combination thereof.

In case that the second electrode UL is a transflective electrode or a reflective electrode, the second electrode UL may include, e.g., Ag, Mg, Cu, Al, Pt, Pd, Au, Ni, Nd, Ir, Cr. Li, Ca, LiF/Ca, LiF/Al, Mo, Ti, Yb, W, or a compound or mixture (e.g., AgMg. AgYb, or MgYb) including the same. As another example, the second electrode UL may have a multilayer structure including a reflective or semi-transmissive film formed of the above material and a transparent conductive film formed of indium tin oxide (ITO), indium zinc oxide (IZO), zinc oxide (ZnO), indium tin zinc oxide (ITZO), or the like, or a combination thereof. For example, the second electrode UL may include the above-described metal materials, a combination of two or more metal materials selected from among the above-described metal materials, or oxides of the above-described metal materials.

The capping layer CPL may be provided on the second electrode UL. The capping layer CPL may include a multilayer or a single layer. The capping layer CPL may be an organic layer or an inorganic layer. For example, in case that the capping layer CPL includes an inorganic material, this inorganic material may contain an alkali metal compound such as LiF, an alkali earth-metal compound such as MgF₂, SiON, SiNₓ, SiO_{y}, or the like, or a combination thereof. Unlike this, in case that the capping layer CPL includes an organic material, this organic material may include a-NPD, NPB. TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), or the like, or a combination thereof, or may include an epoxy resin or acrylate such as methacrylate.

Referring to FIG. 6A, in an embodiment, the first light-emitting layer EML-1 may be disposed on the hole transport region HTR. The second light-emitting layer EML-2 may be disposed on the light-emitting auxiliary portion EA. The third light-emitting layer EML-3 may be disposed between the second light-emitting layer EML-2 and the light-emitting auxiliary portion EA. Referring to FIG. 6B, in an embodiment, the first light-emitting layer EML-1 may be disposed on the hole transport region HTR, the second light-emitting layer EML-2 may be disposed on the light-emitting auxiliary portion EA, and the third light-emitting layer EML-3 may be disposed between the first light-emitting layer EML-1 and the light-emitting auxiliary portion EA. However, this is merely an example, and an embodiment of the disclosure is not limited thereto.

The first light-emitting layer EML-1 may generate blue light, the second light-emitting layer EML-2 may generate red light, and the third light-emitting layer EML-3 may generate green light. Unlike this, the first light-emitting layer EML-1 may generate green light, the second light-emitting layer EML-2 may generate blue light, and the third light-emitting layer EML-3 may generate red light. As another example, the first light-emitting layer EML-1 may generate red light, the second light-emitting layer EML-2 may generate green light, and the third light-emitting layer EML-3 may generate blue light.

Hereinafter, a method of manufacturing a display panel according to an embodiment of the disclosure will be described. In the description of the method of manufacturing the display panel according to an embodiment, descriptions of overlapping contents of the display panel according to the above-described embodiment will be omitted.

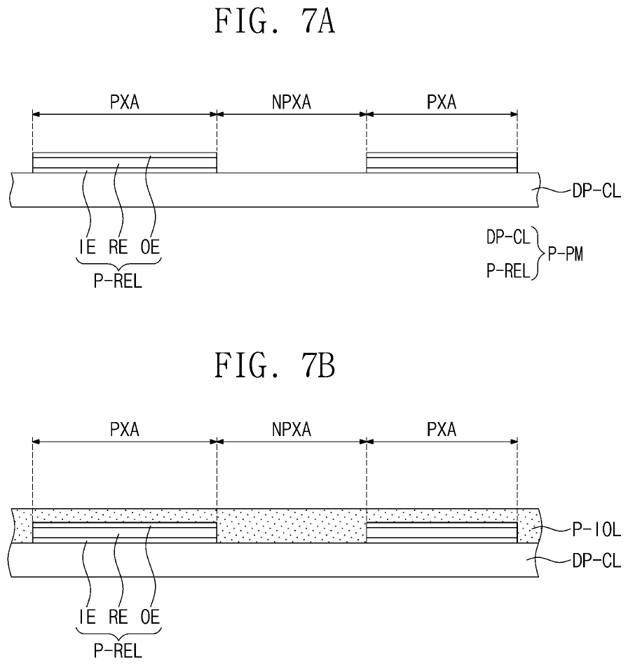

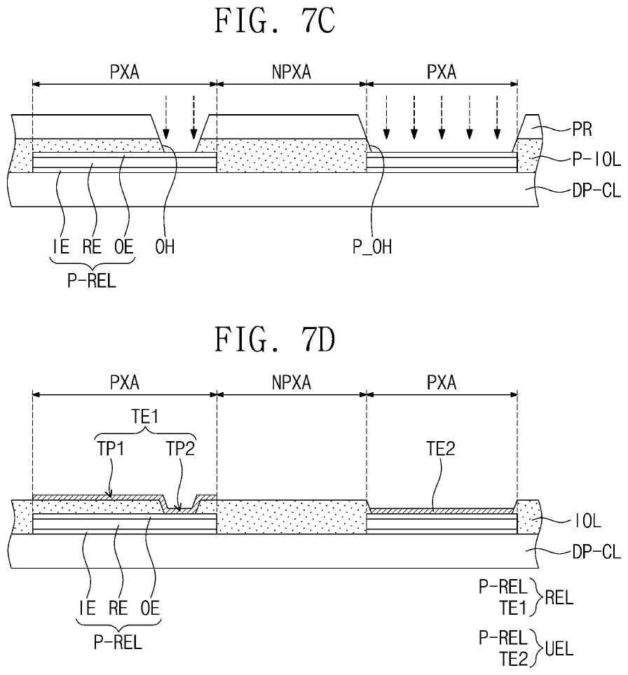

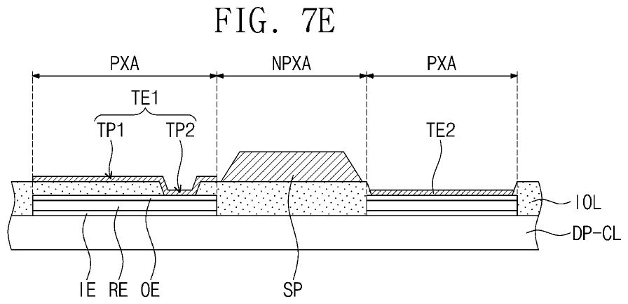

FIGS. 7A to 7E are schematic cross-sectional views each illustrating some operations in a method of manufacturing a display panel according to an embodiment of the disclosure.

Referring to FIG. 7A, the method of manufacturing the display panel according to an embodiment of the disclosure may include providing a preliminary panel member P-PM including a circuit layer DP-CL and a preliminary resonance electrode P-REL. The preliminary resonance electrode P-REL may overlap the pixel region PXA, and may have a structure in which a lower oxidation electrode IE, a reflective electrode RE, and the oxidation electrode OE are sequentially stacked each other.

Referring to FIG. 7B, the method of manufacturing the display panel according to an embodiment of the disclosure may include forming a preliminary inorganic layer P-IOL on a preliminary panel member P-PM. The preliminary inorganic layer P-IOL may be formed to overlap the pixel region PXA and the non-pixel region NPXA. The preliminary inorganic layer P-IOL may be formed to be disposed directly on the oxidation electrode OE and the circuit layer DP-CL. The preliminary inorganic layer P-IOL may be made of a silicon-containing inorganic material.

Referring to FIGS. 7B and 7C, the method of manufacturing the display panel according to an embodiment of the disclosure may include forming the inorganic layer IOL by forming the opening OH in the preliminary inorganic layer P-IOL. The opening OH may expose an upper surface of the oxidation electrode OE. The opening OH may expose only a portion of the upper surface of the oxidation electrode OE, and leave other portions unexposed. Accordingly, a portion of the preliminary inorganic layer P-IOL formed on the oxidation electrode OE may remain without being etched. The unetched portion of the preliminary inorganic layer P-IOL formed on the oxidation electrode OE may be defined as a second portion P2 (see FIG. 5A) of the inorganic layer IOL (see FIG. 5A).

The forming of the inorganic layer IOL may include forming the pixel opening P_OH in the preliminary inorganic layer P-IOL. The pixel opening P_OH may expose at least a portion or all of the upper surface of the oxidation electrode OE. The forming of the opening OH and the forming of the pixel opening P_OH may be performed simultaneously.

The forming of the opening OH and the pixel opening P_OH may be performed by a photoresist process. The photoresist process may include forming a photoresist layer PR to entirely overlap the upper surface of the preliminary inorganic layer P-IOL. After that, the process may include performing exposure and development processes on the photoresist layer PR overlapping the opening OH and the pixel opening P_OH. The forming of the opening OH and the pixel opening P_OH may include an etching process after the photoresist process. The process may include performing an etching process on the preliminary inorganic layer P-IOL which overlap the opening OH and the pixel opening P_OH by disposing a mask (not shown) in a region other than the developed photoresist layer PR. Accordingly, the preliminary inorganic layer P-IOL disposed in the opening OH and the pixel opening P_OH may be etched.

Referring to FIG. 7D, the method of manufacturing the display panel according to an embodiment of the disclosure may include forming a first transparent electrode TE1 on the inorganic layer IOL and in the opening OH. The first transparent electrode TE1 may include the first transparent portion TP1 formed on the inorganic layer IOL and the second transparent portion TP2 formed in the opening OH. The first transparent electrode TE1 may be formed on a lower surface of the opening OH and a side surface of the opening OH. The first transparent electrode TE1 may not be formed on a side surface of the pixel opening P_OH. The forming of the first transparent electrode TEL and the forming of the second transparent electrode TE2 may be performed simultaneously.

Referring to FIG. 7E, the method of manufacturing the display panel according to an embodiment of the disclosure may further include forming a spacer SP disposed on the inorganic layer IOL. The spacer SP may overlap the non-pixel region NPXA and may be disposed directly on the inorganic layer IOL to serve to divide the pixel region PXA.

Referring to FIGS. 7E and 4A, the method of manufacturing a display panel according to an embodiment of the disclosure may include forming the light-emitting portion EP on the first transparent electrode TE1 after the forming the first transparent electrode TE1 or the forming of the spacer SP. The light-emitting portion EP may be formed as a common layer on the first transparent electrode TE1 and the second transparent electrode TE2.

A display panel according to an embodiment of the disclosure may implement excellent display resolution and improved luminous efficiency by including a first resonance electrode in a light-emitting element or light-emitting elements. According to the disclosure, the resonance distance may be adjusted to have an optimal resonance frequency by designing the thickness of the first resonance electrode in the light-emitting element according to the wavelength of light to be output, so that excellent or desired display resolution may be achieved. In addition, in the first resonance electrode according to an embodiment, a second portion functioning as a resonance auxiliary layer may be provided as an inorganic layer having a low extinction coefficient. Accordingly, the display panel according to an embodiment of the disclosure may achieve high luminous efficiency as well as high resolution through excellent optical resonance design. In addition, the display panel according to an embodiment of the disclosure may provide a resonance auxiliary layer by utilizing an inorganic layer defining an inter-pixel region. Accordingly, a method of manufacturing a display panel according to an embodiment may achieve an effect of increasing process efficiency through a mask reduction.

A display panel and an electronic apparatus including the same according to an embodiment may exhibit excellent display efficiency by including an inorganic layer.

A method of manufacturing a display panel according to an embodiment may have excellent process efficiency.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a circuit layer including a pixel region and a non-pixel region defined adjacent to the pixel region;
a first light-emitting element disposed on the circuit layer and overlapping the pixel region; and
an inorganic layer disposed on the circuit layer and including a first portion overlapping the non-pixel region and a second portion extending in a direction from the first portion and overlapping the pixel region, wherein
the first light-emitting element includes:
a first resonance electrode disposed on the circuit layer and including a reflective electrode and a first transparent electrode disposed on the reflective electrode;
a light-emitting portion disposed on the first resonance electrode; and
an upper electrode disposed on the light-emitting portion,
the second portion is disposed between the reflective electrode and the first transparent electrode,
at least one opening is defined in the second portion to expose a portion of an upper surface of the reflective electrode,
the first transparent electrode includes a first transparent portion disposed on the second portion and a second transparent portion disposed within the opening, and
a first length of the first transparent portion in the direction is greater than a second length of the second transparent portion in the direction.

2. The display panel of claim 1, wherein the first transparent portion is disposed directly on the second portion.

3. The display panel of claim 1, wherein the second transparent portion contacts the reflective electrode through the opening.

4. The display panel of claim 1, wherein the second transparent portion entirely overlaps a side surface of the opening.

5. The display panel of claim 1, wherein a material included in the first portion and a material included in the second portion each comprise at least one of silicon nitride, silicon oxynitride, and silicon oxide.

6. The display panel of claim 1, wherein the reflective electrode comprises at least one of silver (Ag), magnesium (Mg), aluminum (Al), platinum (Pt), lead (Pd), gold (Au), nickel (Ni), neodymium (Nd), iridium (Ir), and chromium (Cr).

7. The display panel of claim 1, wherein the first transparent electrode comprises indium tin oxide (ITO).

8. The display panel of claim 1, wherein
the first resonance electrode further includes an oxidation electrode disposed on the reflective electrode, and
the second transparent portion contacts the oxidation electrode through the opening.

9. The display panel of claim 8, wherein the oxidation electrode comprises indium gallium zinc oxide (IGZO).

10. The display panel of claim 1, further comprising:
a second light-emitting element spaced apart from the first light-emitting element on a plane and disposed on the circuit layer,
wherein the second light-emitting element includes:
a second resonance electrode having the reflective electrode and a second transparent electrode disposed on the reflective electrode;
the light-emitting portion disposed on the second resonance electrode; and
the upper electrode.

11. The display panel of claim 10, wherein a thickness of the second resonance electrode is smaller than a thickness of the first resonance electrode.

12. The display panel of claim 10, wherein the second portion is not disposed between the reflective electrode and the second transparent electrode.

13. The display panel of claim 10, wherein the first portion is disposed between the first light-emitting element and the second light-emitting element and divides the first light-emitting element and the second light-emitting element.

14. The display panel of claim 10, wherein
the second resonance electrode further comprises an oxidation electrode disposed on the reflective electrode, and
a lower surface of the second transparent electrode entirely overlaps an upper surface of the oxidation electrode.

15. The display panel of claim 10, wherein
a pixel opening is defined in the first portion, and
the pixel opening exposes an upper surface of the reflective electrode.

16. The display panel of claim 1, further comprising:
a spacer disposed on the first portion and overlapping the non-pixel region.

17. A method of manufacturing a display panel, the method comprising:
providing a preliminary panel member including a circuit layer having a pixel region and a non-pixel region extending from the pixel region in a direction and a preliminary resonance electrode which is disposed on the circuit layer and overlaps the pixel region and in which a reflective electrode and an oxidation electrode are sequentially stacked;
forming a preliminary inorganic layer on the preliminary panel member to overlap the pixel region and the non-pixel region;
forming an inorganic layer by forming, in the preliminary inorganic layer, an opening exposing at least a portion of the oxidation electrode;
forming a first transparent electrode in the opening and on the inorganic layer to overlap the pixel region; and
forming a light-emitting portion on the first transparent electrode, wherein
the first transparent electrode includes a first transparent portion disposed on the inorganic layer and a second transparent portion disposed in the opening, and
a first length of the first transparent portion in the direction is greater than a second length of the second transparent portion in the direction.

18. The method of claim 17, wherein the forming of the inorganic layer is performed by a photoresist process.

19. The method of claim 17, wherein
the forming of the inorganic layer comprises forming a pixel opening spaced apart from the opening on a plane and defined in the inorganic layer, and
the first transparent electrode is not formed on a side surface within the pixel opening but is formed on a side surface within the opening.

20. The method of claim 17, further comprising:
after the forming of the first transparent electrode, forming a spacer disposed on the inorganic layer to overlap the non-pixel region.

21. An electronic apparatus comprising:
a display panel; and
a lens unit facing the display panel, the display panel including:
a circuit layer including a pixel region and a non-pixel region defined adjacent to the pixel region;
a first light-emitting element disposed on the circuit layer and overlapping the pixel region; and
an inorganic layer disposed on the circuit layer and including a first portion overlapping the non-pixel region and a second portion extending in a direction from the first portion and overlapping the pixel region, wherein
the first light-emitting element includes:
a first resonance electrode disposed on the circuit layer and including a reflective electrode and a first transparent electrode disposed on the reflective electrode;
a light-emitting portion disposed on the first resonance electrode; and
an upper electrode disposed on the light-emitting portion,
the second portion is disposed between the reflective electrode and the first transparent electrode,
at least one opening is defined in the second portion to expose a portion of an upper surface of the reflective electrode,
the first transparent electrode includes a first transparent portion disposed on the second portion and a second transparent portion disposed within the opening, and
a first length of the first transparent portion in the direction is greater than a second length of the second transparent portion in the direction.
